(19) United States
(12) Patent Application Publication
(10) Pub. No.: US 2026/0011667 A1
(43) Pub. Date: Jan. 8, 2026

(54) MEMORY DEVICE AND METHOD FOR TESTING THE SAME

(71) Applicant: Samsung Electronics Co., Ltd., Suwon-si (KR)

(72) Inventors: Sang-Hoon JUNG, Suwon-si (KR); Young Seok PARK, Suwon-si (KR); Young Hun SEO, Suwon-si (KR); Hyun-Chul YOON, Suwon-si (KR)

(73) Assignee: Samsung Electronics Co., Ltd., Suwon-si (KR)

(21) Appl. No.: 18/983,661

(22) Filed: Dec. 17, 2024

(30) Foreign Application Priority Data
Jul. 4, 2024 (KR) 10-2024-0087964

(51) Int. Cl. H01L 23/00; H01L 25/00; H01L 25/065; H01L 25/18; H10B 80/00

(52) U.S. Cl. CPC H01L 24/06; H01L 24/08; H01L 24/80; H01L 25/0657; H01L 25/18; H01L 25/50; H10B 80/00; H01L 2224/06131; H01L 2224/06179; H01L 2224/06515; H01L 2224/08145; H01L 2224/80895; H01L 2224/80896; H01L 2224/80908; H01L 2225/06513; H01L 2225/06541; H01L 2924/1431; H01L 2924/1436

(57) ABSTRACT

There is provided a memory device including a first chip including a first normal region, the first region including a plurality of first normal connectors on a first surface and configured to be provided with signals used during an operation of memory cells, and a first test region including a plurality of first connectors on the first surface and electrically connected to each other, and a second chip. The second chip includes a second normal region including a plurality of second normal connectors, and configured to provide signals used during the operation of the memory cells to the first normal connectors, and a second test region including a plurality of first and second test connectors on the second surface so as not to overlap the plurality of first connectors in the first direction, and configured to not be provided with signals used during the operation of the memory cells.

### CROSS-REFERENCE TO RELATED APPLICATION

This application claims priority from Korean Patent Application No. 10-2024-0087964 filed on Jul. 4, 2024, in the Korean Intellectual Property Office, and all the benefits accruing therefrom under 35 U.S.C. 119, the contents of which in its entirety are herein incorporated by reference.

### BACKGROUND

Some example embodiments relate to a memory device and/or a method for testing the same.

A dynamic random access memory (DRAM) may be manufactured by bonding a first wafer having a memory cell to a second wafer including a peripheral logic. By bonding the first and second wafers, a word line and a bit line of the first wafer are electrically connected to a sub-word line driver (SWD) and a sense amplifier (bit line sense amplifier or BLSA) of the second wafer. When bonding the first and second wafers, a misalignment failure in which an alignment between the first and second wafers warps may occur. Since sorting out chips in which the misalignment failure occurs is expected to be done before proceeding to the next step of the process, testing whether a misalignment occurs after bonding may be desirable, and researches for a simple and/or quick misalignment test are being conducted to reduce time and/or to reduce costs.

### SUMMARY

Some example embodiments provide a memory device capable of performing a simple and/or quick misalignment test.

Alternatively or additionally, some example embodiments may also provide a method for testing the memory device capable of performing a simple and/or quick misalignment test.

According to some example embodiments, there is provided a memory device comprising a first chip including a first normal region that includes a plurality of first normal connectors on a first surface and configured to be provided with signals used for an operation of memory cells, and a first test region that includes a plurality of first connectors on the first surface and electrically connected to each other, and a second chip bonded to the first chip in a first direction. The second chip includes a second normal region including a plurality of second normal connectors on a second surface touching with the first surface to at least partially overlap the plurality of first normal connectors in the first direction, and configured to provide signals used for the operation of the memory cells to the first normal connectors, and a second test region including a plurality of first and second test connectors on the second surface so as not to overlap the plurality of first connectors in the first direction, the plurality of first and second connectors configured to not be provided with signals used for the operation of the memory cells.

Alternatively or additionally according to some example embodiments, there is provided a memory device comprising a first chip including a plurality of first connectors on a first surface and electrically connected to each other, a second chip bonded to the first chip in a first direction, and including a plurality of first and second test connectors on a second surface touching with the first surface so as not to overlap the plurality of first connectors in the first direction, and first and second probing pads configured to perform a misalignment test, wherein the plurality of first test connectors are connected to the first probing pad, and the plurality of second test connectors are connected to the second probing pad, and the plurality of first connectors and the plurality of first and second test connectors are configured to not be used to send and receive signals associated with the operation of memory cells.

Alternatively or additionally according to some example embodiments, there is provided a memory device comprising a first chip which includes a plurality of first connectors on a first surface facing a first direction and electrically connected to each other, and a second chip bonded to the first chip in the first direction, and including a plurality of first and second test connectors on a second surface touching with the first surface so as not to overlap the plurality of first connectors in the first direction. The plurality of first test connectors are configured to be supplied with a first voltage during a misalignment test, and the plurality of second test connectors are configured to be supplied with a second voltage different from the first voltage during the misalignment test.

Alternatively or additionally according to some example embodiments, there is provided a method for testing a memory device, the method comprising providing a first chip including a first normal region that includes a plurality of first normal connectors on a first surface, and a first test region including a plurality of first connectors on the first surface and electrically connected to each other, providing a second chip including a second normal region including a plurality of second normal connectors on the second surface and at least partially overlapping the plurality of first normal connectors in the first direction, and a second test region including a plurality of first and second test connectors on the second surface and disposed so as not to overlap the plurality of first connectors in the first direction, applying a first voltage to the plurality of first test connectors, applying a second voltage different from the first voltage to the plurality of second test connectors, and testing whether a current flows from at least one of the plurality of first test connectors to at least one of the plurality of second test connectors.

However, aspects of example embodiments are not restricted to the one set forth herein. The above and other aspects of example embodiments will become more apparent to one of ordinary skill in the art to which inventive concepts pertains by referencing the detailed description of example embodiments given below.

### BRIEF DESCRIPTION OF DRAWINGS

FIG. 1 is a block diagram showing a memory system according to some example embodiments.

FIG. 2 is a block diagram of the memory device according to some example embodiments.

FIG. 3 is a diagram for explaining a memory device of the CoP structure according to some example embodiments.

FIG. 4 is a diagram for explaining a memory device of a PoC structure according to some example embodiments.

FIG. 5 is a plan view of a memory device according to some example embodiments.

FIG. 6 is a plan view showing a partial region of a first surface of the upper chip according to some example embodiments.

FIG. 7 is a plan view showing a partial region on the second surface of the lower chip according to some example embodiments.

FIG. 8 is a flowchart showing a misalignment test process in the memory device according to some example embodiments.

FIG. 9 is an enlarged plan view showing a partial region in the memory device according to some example embodiments.

FIG. 10 is a cross-sectional view taken along line A-A′ of FIG. 9.

FIG. 11 is a cross-sectional view taken along line B-B′ of FIG. 9.

FIG. 12 is a cross-sectional view taken along C-C′ of FIG. 9.

FIG. 13 is an enlarged plan view showing a partial region of the memory device according to some example embodiments.

FIG. 14 is a cross-sectional view taken along D-D′ of FIG. 13.

FIG. 15 is an enlarged plan view showing a partial region of the memory device according to some example embodiments.

FIG. 16 is a plan view showing a partial region on the first surface of the upper chip according to some example embodiments.

FIG. 17 is a plan view showing a partial region on the second surface of the lower chip according to some example embodiments.

FIG. 18 is a plan view showing a partial region on the first surface of the upper chip according to some example embodiments.

FIG. 19 is a plan view showing a partial region on the second surface of the lower chip according to some example embodiments.

FIG. 20 is a plan view of a memory device for explaining a test region according to some example embodiments.

FIG. 21 is a plan view of the memory device for explaining the test region. according to some example embodiments

FIG. 22 is a plan view of the memory device for explaining the test region according to some example embodiments.

FIG. 23 is a block diagram showing a memory system according to some example embodiments.

FIG. 24 is a diagram of a semiconductor package according to some example embodiments.

FIG. 25 is a diagram of an implemented example of a semiconductor package according to some example embodiments.

FIG. 26 is a diagram of a semiconductor package according to some example embodiments.

### DETAILED DESCRIPTION OF SOME EXAMPLE EMBODIMENTS

Hereinafter, some example embodiments according to the technical idea of inventive concepts will be described with reference to the accompanying drawings.

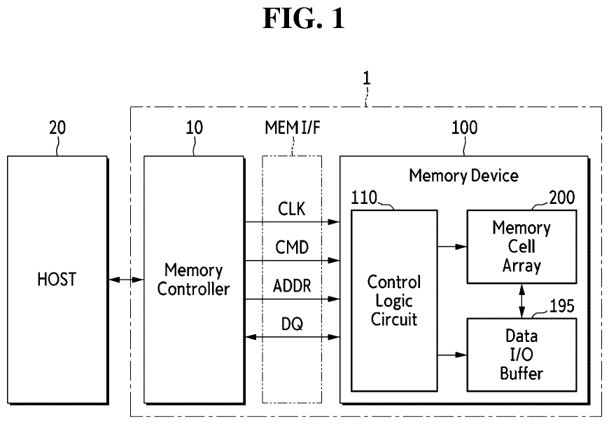

FIG. 1 is a block diagram showing a memory system according to some example embodiments.

Referring to FIG. 1, the memory system may include a host device 20 and a memory storage device 1. The memory storage device 1 may include a memory device 100 and a memory controller 10.

The memory controller 10 may control at least some or up to all, e.g., the overall operation of the memory device 100. For example, the memory controller 10 may control a data exchange between the external host device 20 and the memory device 100. For example, the memory controller 10 may control the memory device 100 according to a request from the host device 20, and may write data and/or read data therethrough.

The memory controller 10 and the memory device 100 may communicate with each other through a memory interface (MEM I/F). Alternatively or additionally the memory controller 10 and the external host device 20 may also communicate with each other through a host interface. In some example embodiments, the memory controller 10 may mediate signals between the memory device 100 and the host device 20. The memory controller 10 may apply a command CMD for controlling the memory device 100 to control the operation of the memory device 100. Here, the memory device 100 may include dynamic memory cells. For example, the memory device 100 may include one or more of a DRAM (dynamic random access memory), a DDR4 (double data rate 4), a SDRAM (synchronous DRAM), a LPDDR4 (low power DDR4) SDRAM, a LPDDR5 SDRAM, or the like. However, example embodiments are not limited thereto, and the memory device 100 may alternatively or additionally include a non-volatile memory device such as a NAND device and/or a phase-change RAM (PCRAM) device. However, the memory device 100 will be described as a volatile memory device.

The memory controller 10 may transmit one or more of a clock signal CLK, a command CMD, an address ADDR, or the like to the memory device 100. The memory controller 10 may provide data DQ to the memory device 100, and may receive the data DQ from the memory device 100. The memory device 100 may include a memory cell array 200 in which the data DQ is stored, a control logic circuit 110, a data input/output buffer 195, and the like.

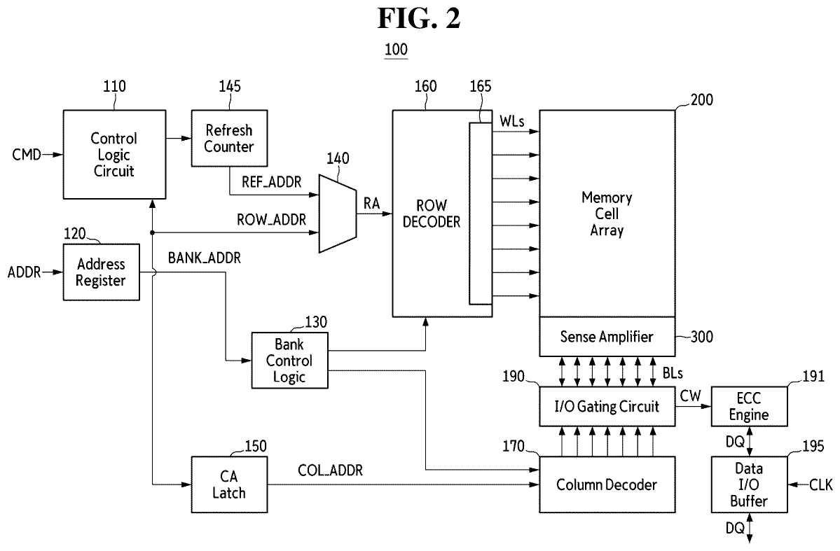

FIG. 2 is a block diagram of the memory device.

Referring to FIG. 2, the memory device 100 may include a control logic circuit 110, an address register 120, a bank control logic circuit 130, a row address multiplexer 140, a refresh counter 145, a column address latch 150, a row decoder 160, a sub-word line driver 165, a column decoder 170, a memory cell array 200, a sense amplifier 300, an input/output gating circuit 190, an ECC engine 191, a data input/output buffer 195, and the like.

The memory cell array 200 may include a plurality of bank memory arrays. The row decoder 160 may be connected to the plurality of bank memory arrays through the sub-word line driver 165. The column decoder 170 may be connected to the plurality of bank memory arrays. The sense amplifier 300 may be connected to each of the plurality of bank memory arrays. The memory cell array 200 may include a plurality of word lines, a plurality of bit lines, and a plurality of memory cells formed at a point on which the word lines and the bit lines intersect each other.

The address register 120 may be provided with an address ADDR from the memory controller 10. The address ADDR may include a bank address BANK_ADDR, a row address ROW_ADDR, a column address COL_ADDR, and the like. The address register 120 may provide the bank address BANK_ADDR to the bank control logic circuit 130. The address register 120 may provide the row address ROW_ADDR to the row address multiplexer 140. The address register 120 may provide the column address COL_ADDR to the column address latch 150.

The bank control logic circuit 130 may generate a bank control signal in response to the bank address BANK_ADDR. The bank row decoder 160 may be activated in response to the bank control signal. In some example embodiments, the column decoder 170 may be activated in response to the bank control signal corresponding to the bank address BANK_ADDR.

The row address multiplexer 140 may receive the row address ROW_ADDR from the address register 120, and may receive the refresh row address REF_ADDR from the refresh counter 145. The row address multiplexer 140 may select either the row address ROW_ADDR or the refresh row address REF_ADDR, and output it to the row address RA. The row address RA may be transferred to the row decoder 160.

The refresh counter 145 may sequentially output the refresh row address REF_ADDR according to the control of the control logic circuit 110.

The row decoder 160 activated by the bank control logic circuit 130 may decode the row address RA that is output from the row address multiplexer 140, and activate a word line corresponding to the row address RA through the sub-word line driver 165. For example, the row decoder 160 may apply a word line driving voltage to the word line corresponding to the row address RA through the sub-word line driver 165.

The column address latch 150 may receive the column address COL_ADDR from the address register 120, and temporarily store the received column address COL_ADDR. The column address latch 150 may gradually increase the column address COL_ADDR received in a burst mode. The column address latch 150 may provide the temporarily stored column address COL_ADDR and/or the gradually increased column address COL_ADDR to the column decoder 170.

The column decoder 170 activated by the bank control logic circuit 130 among the column decoders 170 may activate the sense amplifier 300 corresponding to the bank address BANK_ADDR and the column address COL_ADDR through the corresponding input/output gating circuit 190.

The input/output gating circuit 190 may include a circuit for gating the input/output data, an input data mask logic, reading data latches for storing the data that is output from the memory cell array 200, and writing drivers for writing the data to the memory cell array 200.

A code word CW that is read from the bank memory array of the memory cell array 200 may be sensed by the sense amplifier 300 corresponding to the bank memory array. In some example embodiments, the code word CW may be stored in the reading data latch. The code word CW stored in the reading data latch may be subjected to ECC decoding by the ECC engine 191, and the data DQ subjected to the ECC decoding may be provided to the memory controller 10 through the data input/output buffer 195.

The data input/output buffer 195 may provide the data DQ to the ECC engine 191 on the basis of the clock signal CLK in a writing operation. The data input/output buffer 195 may provide the data DQ provided from the ECC engine 191 to the memory controller 10 on the basis of the clock signal CLK in a reading operation.

The memory cell array 200 may be connected to the sense amplifier 300, and the row decoder 160 and the column decoder 170 may be connected to the memory cell array 200 and the sense amplifier 300. At this time, a plurality of bit lines included in the memory cell array 200 may be connected to the sense amplifier 300 in an open bit line structure.

The memory device 100 may have a C2C (chip to chip) structure. The C2C structure may mean or may indicate (or refer to) a structure in which a cell chip including a cell region is manufactured, a logic chip including a peripheral circuit (PERI) region is manufactured, and then the cell chip and the logic chip are connected to, e.g., bonded to, each other. For example, the cell region may include a memory cell array 200. The peripheral circuit region may include a control logic circuit 110, an address register 120, a bank control logic circuit 130, a row address multiplexer 140, a refresh counter 145, a column address latch 150, a row decoder 160, a sub-word line driver 165, a column decoder 170, a sense amplifier 300, an input/output gating circuit 190, an ECC engine 191, a data input/output buffer 195, and the like. However, example embodiments are not limited thereto, and each of the cell region and the peripheral circuit region may include more different configurations or include less different configurations. The C2C structure of the memory device 100 may be divided into a CoP (Cell-on-Peri) structure and a PoC (Peri-on-Cell) structure. In the CoP structure, the cell chip may be an upper chip, and the logic chip may be a lower chip. In the PoC structure, the cell chip may be the lower chip, and the logic chip may be the upper chip.

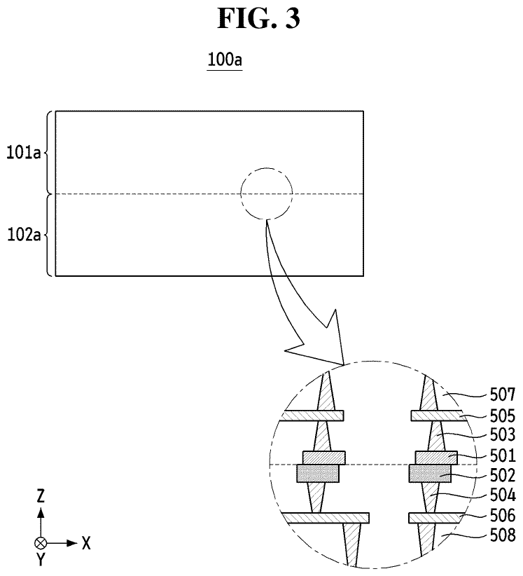

FIG. 3 is a diagram for explaining a memory device of the CoP structure.

Referring to FIG. 3, the memory device 100a of the CoP structure may be formed through a method of bonding and electrically connecting a bonding pad 501 formed on the uppermost metal layer of the upper chip 101a which is or includes a cell chip, and a bonding pad 502 formed on the uppermost metal layer of the lower chip 102a which is or includes a logic chip, to touch each other. For example, when the bonding pads 501 and 502 are formed of copper (Cu), the bonding method may be or may include a Cu—Cu bonding method. The bonding pads 501 and 502 may be formed of aluminum and/or of tungsten. The upper chip 101a which is or includes a cell chip may communicate with the lower chip 102a which is or includes a logic chip through an upper wiring line 505, an upper wiring plug 503, an upper bonding pad 501, a lower bonding pad 502, a lower wiring plug 504, and a lower wiring line 506. The upper chip 101a which is a cell chip may further include an upper insulating film 507, and the upper insulating film 507 may include an insulating material. The upper chip 102a which is or includes a logic chip may further include a lower insulating film 508, and the lower insulating film 508 may include an insulating material. The upper wiring line 505, the upper wiring plug 503, the lower wiring plug 504, and the lower wiring line 506 may include a conductive material.

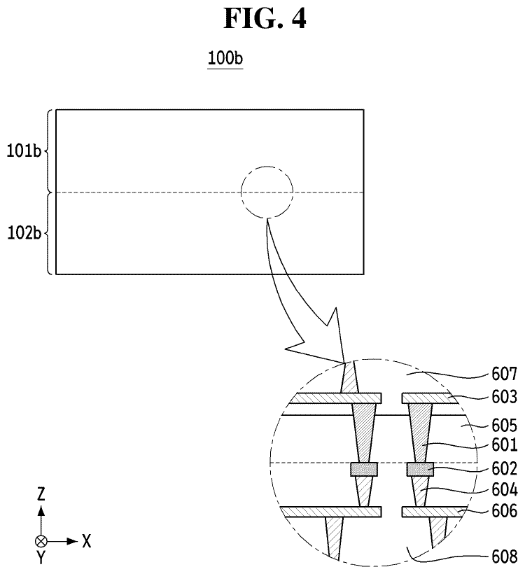

FIG. 4 is a diagram for explaining a memory device of a PoC structure.

Referring to FIG. 4, the memory device 100b of the PoC structure may be formed through a method of bonding and electrically connecting a through via 601 formed to penetrate a substrate inside the upper chip 101b which is the logic chip, and a connecting pad formed in an uppermost metal layer of the lower chip 102b which is the cell chip, to touch each other. The through via 601 penetrates the upper substrate 605, and may be disposed inside the upper substrate 605. The through via 601 may be or may include, for example, a TSV (through-silicon-through) and/or a TDV (through-dielectric-via). The connecting pad 602 may include a conductive material such as one or more of copper, aluminum, or tungsten. The upper chip 101b which is or includes a logic chip may communicate with the lower chip 102b which is or includes a cell chip, through an upper wiring line 603, a through via 601, a lower connecting pad 602, a lower wiring plug 604, and a lower wiring line 606. The upper chip 101b which is the logic chip may further include an upper insulating film 607, and the upper insulating film 607 may include an insulating material. The lower chip 102b which is the cell chip may further include a lower insulating film 608, and the lower insulating film 608 may include an insulating material. The upper wiring line 603, the lower wiring plug 604, and the lower wiring line 606 may include a conductive material.

When the upper chip and the lower chip are bonded and connected, a defect may occur in the bonding process, and a contact area between corresponding connectors between the upper chip and the lower chip (for example, between the upper bonding pad and the lower bonding pad in the case of a memory device of the CoP structure, or between the upper through via and the lower connecting pad in the case of a memory device of the PoC structure) is reduced, which may cause a phenomenon in which a resistance is excessively increased, and/or the corresponding connectors are not connected to each other and in an open circuit with each other (hereinafter referred to as “misalignment” or “misalignment failure”).

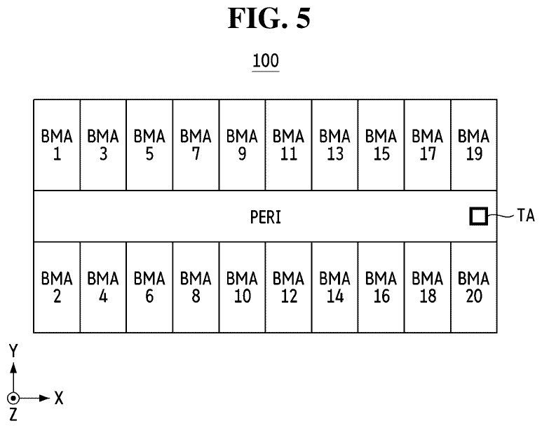

FIG. 5 is a plan view of a memory device.

Referring to FIG. 5, the memory device 100 may include a plurality of bank memory array regions BMA1 to BMA20 and a peripheral circuit region PERI. The number of bank memory array regions is not limited to 20, and this is exemplary.

In some embodiments, the memory device 100 may be disposed in a plane extending in a first direction X and a second direction Y. For example, the memory device 100 may extend in the first direction X and the second direction Y. At this time, the memory device 100 may have a rectangular shape when viewed from above. Each of the plurality of bank memory array regions BMA1 to BMA20 may include a part of the memory cell array 200 of FIG. 2, a part of the row decoder 160 (e.g., the sub-word line driver 165), a sense amplifier 300, and the like. However, example embodiments are not limited thereto, and the plurality of bank memory array regions BMA1 to BMA20 may further include other configurations and/or may not include a specific configuration.

The peripheral circuit region PERI may be disposed in a portion of the memory device 100 except the plurality of bank memory array regions BMA1 to BMA20. For example, the peripheral circuit region PERI may be disposed between the first, third, fifth, seventh, ninth, eleventh, thirteenth, fifteenth, seventeenth, and nineteenth bank memory array regions BMA1, BMA3, BMA5, BMA7, BMA9, BMA11, BMA13, BMA15, BMA17, and BMA19 and the second, fourth, sixth, eighth, tenth, twelfth, fourteenth, sixteenth, eighteenth, and twentieth bank memory array regions BMA2, BMA4, BMA6, BMA8, BMA10, BMA12, BMA14, BMA16, BMA18, and BMA20. The peripheral circuit region PERI may include the control logic circuit 110, the address register 120, the bank control logic circuit 130, the row address multiplexer 140, the refresh counter 145, the row decoder 160, the column decoder 170, the column address latch 150, the input/output gating circuit 190, the ECC engine 191, and the data input/output buffer 195 of FIG. 2. However, example embodiments are not limited thereto, and the peripheral circuit region PERI may further include other components and/or may not include a specific component.

A test region TA may be a region used for testing whether a misalignment occurs between the connector of the upper chip and the connector of the lower chip of the memory device 100. In FIG. 5, the test region TA is shown to be formed inside the peripheral circuit region PERI, but may be formed in other locations without being limited thereto.

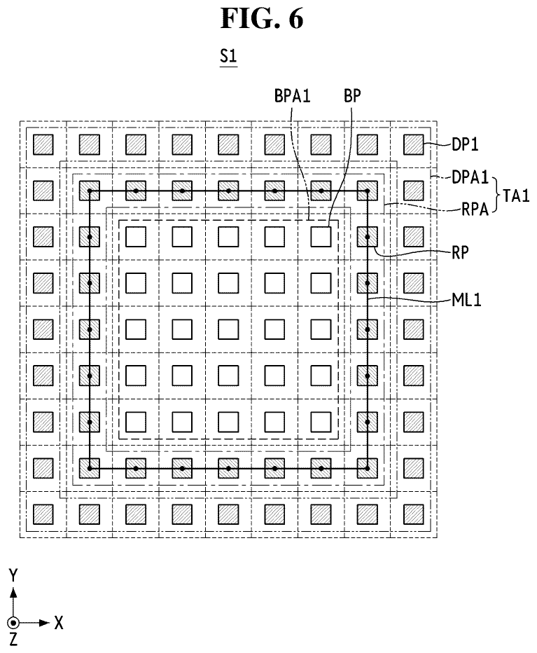

FIG. 6 is a plan view showing a partial region of a first surface of the upper chip.

Referring to FIG. 6, a plurality of connectors may be regularly disposed on the first surface S1 of the upper chip at regular intervals in the second direction X and the third direction Y. The plurality of connectors may be, for example, upper bonding pads (501 of FIG. 3) when the memory device has a CoP structure, or may be through vias (601 of FIG. 4) when the memory device has a PoC structure. Among the plurality of connectors, the plurality of connectors disposed in the first region RPA may be referred to as first connectors RP. The plurality of first connectors RP may be electrically connected to each other. The plurality of first connectors RP may be electrically connected to each other through a first wiring line ML1 inside the upper chip. The first wiring line ML1 may include, for example, a conductive material. The plurality of first connectors RP disposed in the first region RPA may be only for a misalignment test of the memory device (100 of FIG. 1), and may not be a connector for exchanging signals required for or used during the operation of the memory cells of the memory device (100 of FIG. 1). The operation of the memory cells here refers to an operation such as one or more of writing, reading, or erasing the data to the memory cell, and may not include an operation for a misalignment test.

The first region RPA may surround a part of the first normal region BPA1 from the outside. Normal connectors BP disposed in the first normal region BPA1 are not for the misalignment test of the memory device (100 of FIG. 1), but may be connector for sending and receiving a signal required for or used during the operation of the memory cells of the memory device (100 of FIG. 1). However, according to some example embodiments, the normal connectors BP disposed in the first normal region BPA1 may be dummy connectors that are not used for the operation of the memory device (100 of FIG. 1), e.g., that are electrically disconnected or isolated or in a floating state during normal operation of the memory device.

The first dummy region DPA1 may surround the first region RPA from the outside. Among the plurality of connectors, each of the connectors disposed in the first dummy region DPA1 may be referred to as a first dummy connector DP1. A plurality of first dummy connectors DP1 may not be electrically connected to each other, unlike the plurality of first connectors RP. The plurality of first dummy connectors DP1 are only for the misalignment test of the memory device (100 of FIG. 1), and may not be connectors for sending and receiving the signal required for or used during the operation of the memory cells of the memory device (100 of FIG. 1).

The first region RPA and the first dummy region DPA1 may define a first test region TAL. For example, the first test region TA1 may be a region obtained by combining the first region RPA and the first dummy region DPA1. In the first surface S1, the region that is not the first test region TA1 may be a first normal region BPA1.

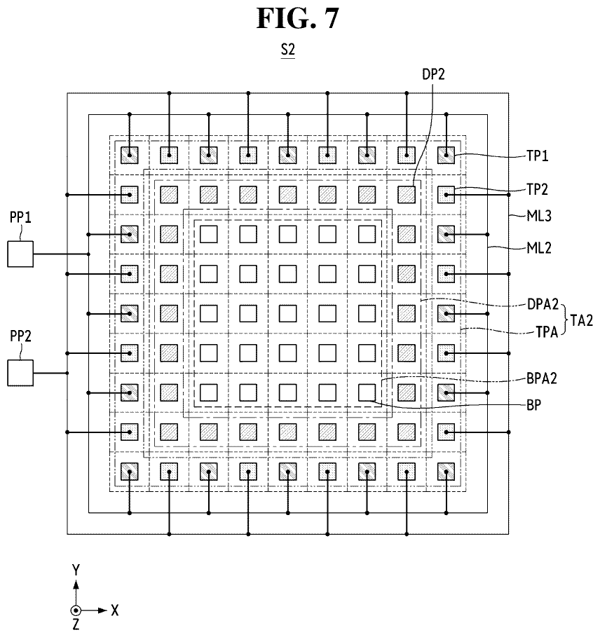

FIG. 7 is a plan view showing a partial region on the second surface of the lower chip.

Referring to FIG. 7, a plurality of connectors may be regularly disposed on the second surface S2 of the lower chip to be spaced apart at regular intervals in the second direction X and the third direction Y. When the upper chip and the lower chip are bonded, the second surface S2 may be a surface that touches the first surface (S1 of FIG. 6) of the upper chip. The plurality of connectors may be, for example, lower bonding pads (502 of FIG. 3) when the memory device has the CoP structure, or may be connecting pads (602 of FIG. 4) when the memory device has the PoC structure. Each of the plurality of connectors disposed on the second dummy region DPA2 which is a part of the second surface S2 may also be referred to as a second dummy connector DP2. A plurality of second dummy connectors DP2 may be only for the misalignment test of the memory device (100 of FIG. 1), and may not be connectors for sending and receiving the signals required for or used during the operation of the memory cells of the memory device (100 of FIG. 1). When the upper chip and the lower chip are bonded, each of the plurality of second dummy connectors DP2 may at least partially come into contact with each of the corresponding plurality of first connectors (RP of FIG. 6). For example, when the upper chip and the lower chip are bonded, each of the plurality of second dummy connectors DP2 may at least partially overlap each of the corresponding plurality of first connectors RP in FIG. 6 in the first direction Z.

The second dummy region DPA2 may surround a second normal region BPA2 from the outside. When the upper chip and the lower chip are bonded, the normal connectors BP of the second normal region BPA2 comes into contact with the corresponding normal connector BP of the first normal region BPA1 of FIG. 6, and may send and receive the signals required for or used during the operation of the memory cells of the memory device (100 of FIG. 1). For example, when the upper chip and the lower chip are bonded, each of the normal connectors BP of the plurality of second normal regions BPA2 may at least partially overlap each of the plurality of normal connectors BP of the corresponding first normal region BPA1 of FIG. 6 in the first direction Z. However, according to some example embodiments, the normal connectors BP disposed in the second normal region BPA2 may be dummy connectors that are not used in the operation of the memory device (100 of FIG. 1).

The second region TPA which is a part of the second surface S may surround the second dummy region DPA2 from the outside. The connectors disposed on the second region TPA may be called test connectors. The plurality of test connectors may be only for misalignment testing of the memory device (100 of FIG. 1), but may not be connectors for sending and receiving the signals required for or used during the operation of the memory cells of the memory device (100 of FIG. 1).

When the upper chip and the lower chip are bonded, each of the plurality of test connectors may at least partially come into contact with each of the corresponding plurality of first dummy connectors (DP1 of FIG. 6). For example, when the upper chip and the lower chip are bonded, each of the plurality of test connectors may at least partially overlap each of the corresponding plurality of first dummy connectors (DP1 of FIG. 6) in the first direction Z.

The plurality of test connectors may be divided into a first test connector TP1 and a second test connector TP2. The plurality of first test connectors TP1 and the plurality of second test connectors TP2 may be disposed alternately adjacent to each other in the second region TPA. The plurality of first test connectors TP1 may be electrically connected to each other through the second wiring line ML2 inside the lower chip. The plurality of first test connectors TP1 may be electrically connected to the first probing pad PP1 through the second wiring line ML2. The plurality of second test connectors TP2 may be electrically connected to each other through a third wiring line ML3 inside the lower chip. The plurality of second test connectors TP2 may be electrically connected to a second probing pad PP2 through the third wiring line ML3.

The first and second probing pads PP1 and PP2 may be disposed, for example, on the uppermost surface of the upper chip that faces the first direction Z, but are not limited thereto, and may be disposed in other locations. The first and second probing pads PP1 and PP2 may be connected to the first test connector TP1 and the second test connector TP2 of the lower chip through a plurality of connectors connected in parallel. Therefore, even when a misalignment occurs in the memory device 100, the first and second probing pads PP1 and PP2 may be electrically connected to the plurality of first and second test connectors TP2. However, the method of connecting the first and second probing pads PP1 and PP2 to the plurality of first and second test connectors TP2 is not limited thereto, and may be connected by other methods.

The second region TPA and the second dummy region DPA2 may define a second test region TA2. For example, the second test region TA2 may be a region obtained by combining the second region TPA and the second dummy region DPA2. In the second surface S2, the region that is not the second test region TA2 may be the second normal region BPA2.

As described above, although the first surface S1 of FIG. 6 is described as one surface of the upper chip, and the second surface S2 is described as one surface of the lower chip, the first surface S1 may be one surface of the lower chip, and the second surface S2 may be one surface of the upper chip according to an embodiment.

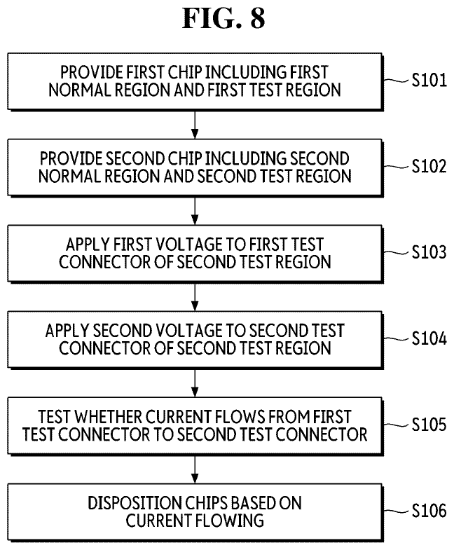

FIG. 8 is a flowchart showing a misalignment test process in the memory device.

Referring to FIG. 8, a first chip including a first normal region and a first test region is provided for the misalignment test (S101). The first chip may be, for example, the upper chip described in FIG. 5. A second chip including a second normal region and a second test region is provided for the misalignment test (S102). The second chip may be, for example, the lower chip described in FIG. 7.

A first voltage is applied to a first test connector of the second test region (S103). For example, the first test connector may be the first test connector (TP1) of FIG. 7. During the misalignment test after bonding the first chip and the second chip, a first voltage VEXT may be applied to the plurality of first test connectors TP1. The first voltage VEXT may be applied from a device (e.g., a probe) outside the memory device 100 through the first probing pad PP1 of FIG. 7. The first voltage VEXT may be applied to the plurality of first test connectors TP1 through the first probing pad PP1 of FIG. 7.

A second voltage is applied to the second test connector of the second test region (S104). For example, the second test connector may be the second test connector TP2 of FIG. 6. During the misalignment test after bonding of the first chip and the second chip, a second voltage VSS may be applied to the plurality of second test connectors TP2. The second voltage VSS may be applied from a device (e.g., a probe) outside the memory device 100 through the second probing pad PP2 of FIG. 7. The second voltage VSS may be applied to the plurality of second test connectors TP2 through the second probing pad PP2 of FIG. 7.

During the test, a check may be made as to whether a current flows from the first test connector to the second test connector (S105). For example, if a short circuit is formed between at least a part of the plurality of first test connectors TP1 and at least a part of the plurality of second test connectors TP2, a current may flow between the plurality of first test connectors TP1 and the second test connector TP2 due to a voltage difference. Since the plurality of first test connectors TP1 are electrically connected to the first probing pad PP1 and the plurality of second test connectors TP2 are electrically connected to the second probing pad PP2, when a current flows between the plurality of first test connectors TP1 and the second test connector TP2 due to a voltage difference, a current may flow between the first probing pad PP1 and the second probing pad PP2. Therefore, the current flow may be tested through the first probing pad PP1 and the second probing pad PP2. If the current flow is not checked as a result of the test, it may be evaluated that no misalignment has occurred or that the misalignment is at an allowable level. As a result of the test, if a current flow is checked, it may be evaluated that a misalignment has occurred, or that the misalignment is at an unallowable level.

A disposition of the chips may be made based on the current flowing (S106). In some example embodiments, chips that are determined to be misaligned may be scrapped or reworked, or downgraded. In some example embodiments, chips that are determined to not be misaligned may continue on to other packaging processes. Alternatively or additionally in some example embodiments, a process, such as a process of bonding wafers to one another, may be improved based on whether current flows from a first test connector to a second test connector. Example embodiments are not limited thereto.

According to some embodiments, because a separate misalignment test circuit is not introduced when testing a misalignment in the memory device, the cost of the misalignment test may be significantly reduced. Alternatively or additionally, a misalignment may be more easily detected by simply checking the current flow, and the test time may be significantly reduced. Alternatively or additionally, the reliability of the misalignment test may be significantly improved, because it is possible to test for and/or react to a problem in which a circuit introduced for the misalignment test malfunctions due to the misalignment.

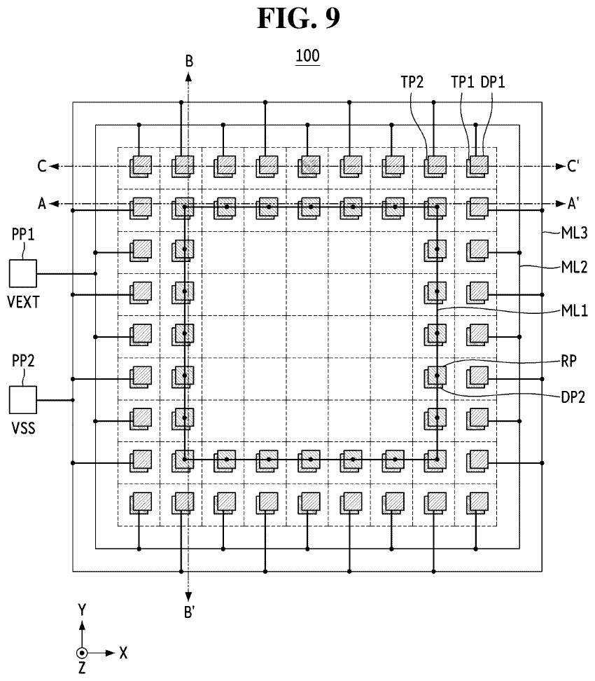

FIG. 9 is an enlarged plan view showing a partial region in the memory device.

Referring to FIG. 9, the first connector RP, the plurality of first and second test connectors TP1 and TP2, and the plurality of first and second dummy connectors DPA1 and DPA2 are shown when the memory device 100 is viewed in the first direction Z after the upper chip and the lower chip are bonded. Other connectors other than the shown connectors will not be shown for brevity. Further, the above-mentioned first to third wiring lines ML1 to ML3, the plurality of first connectors RP, the plurality of first and second test connectors TP1 and TP2, the plurality of first and second dummy connectors DPA1 and DPA2, and the first and second probing pads PP1 and PP2 will not be described.

The upper chip and the lower chip may be bonded such that each of the plurality of first dummy connectors DP1 of the first dummy region DPA1 at least partially overlaps the plurality of first and second test connectors TP1 and TP2 in the corresponding second region TPA, and each of the plurality of first connectors RP of the first region RPA at least partially overlaps the plurality of second dummy connectors DP2 of the corresponding second dummy region DPA2.

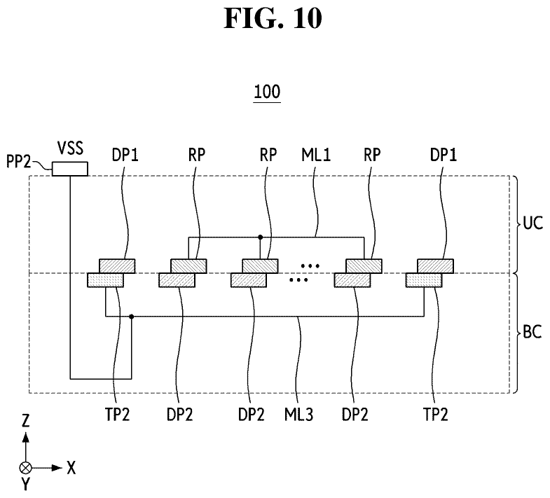

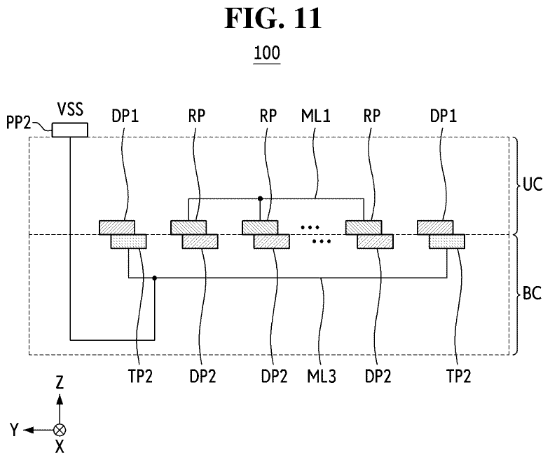

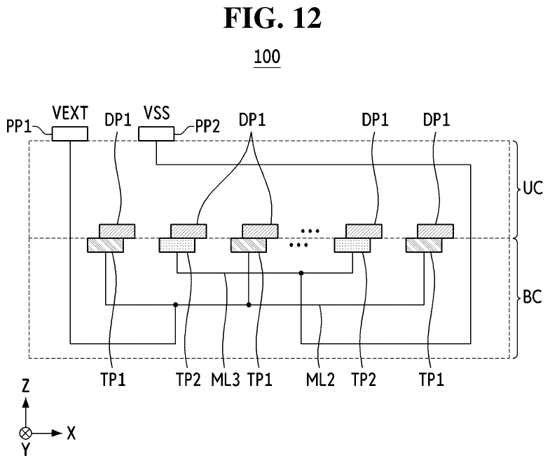

FIG. 10 is a cross-sectional view taken along line A-A′ of FIG. 9. FIG. 11 is a cross-sectional view taken along line B-B′ of FIG. 9. FIG. 12 is a cross-sectional view taken along C-C′ of FIG. 9.

Referring to FIGS. 10 to 12, each of the plurality of first connectors RP of the upper chip UC may at least partially overlap each of the plurality of second dummy connectors DP2 of the corresponding lower chip BC, and each of the plurality of first and second test connectors TP1 and TP2 of the lower chip BC may at least partially overlap the first dummy connector DP1 of the upper chip UC. At this time, the plurality of first and second test connectors TP1 and TP2 may not overlap the plurality of first connectors RP in the first direction Z.

As described above, the plurality of first dummy connectors DP1 may not be electrically connected to each other. Therefore, when each of the plurality of first and second test connectors TP1 and TP2 at least partially overlaps the first dummy connector DP1 in the first direction Z, and does not overlap the plurality of first connectors RP in the first direction Z, a short circuit may not be formed between at least a part of the first test connector TP1 and at least a part of the second test connectors TP2. Therefore, when checking the current flow through the first probing pad PP1 and the second probing pad PP2, the current flow may not be checked. Therefore, it may be evaluated that no misalignment occurs in the memory device 100 shown in FIGS. 9 to 12 (or that the misalignment is at an allowable level).

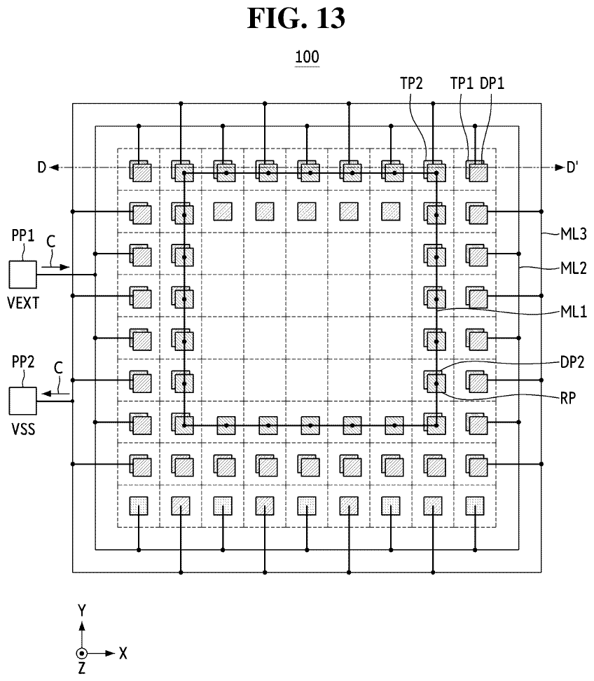

FIG. 13 is an enlarged plan view showing a partial region of the memory device.

FIG. 13 shows the first connector RP, the plurality of first and second test connectors TP1 and TP2, and the plurality of first and second dummy connectors DPA1 and DPA2 when the memory device 100 is viewed in the first direction Z after the upper chip and the lower chip are bonded. The connectors other than the shown connectors will not be shown for brevity. Also, the above-mentioned first to third wiring lines ML1 to ML3, the plurality of first connectors RP, the plurality of first and second test connectors TP1 and TP2, the plurality of first and second dummy connectors DPA1 and DPA2, and the first and second probing pads PP1 and PP2 will not be described.

Referring to FIG. 13, when the upper chip and the lower chip are bonded, unlike FIGS. 9 to 12, the upper chip may further move in the third direction Y beyond the originally intended case, and may be bonded to the lower chip. As a result, some of the plurality of first connectors RP of the upper chip may unintentionally overlap at least partially the first test connector TP1 of the lower chip in the first direction Z, and others of the plurality of first connectors RP may unintentionally overlap at least partially the second test connector TP2 of the lower chip in the first direction Z. In this case, the connectors of the upper chip and the lower chip come into contact with other connectors other than the designating connectors. If the connectors that are not designated to each other come into contact with each other, the memory device may malfunction.

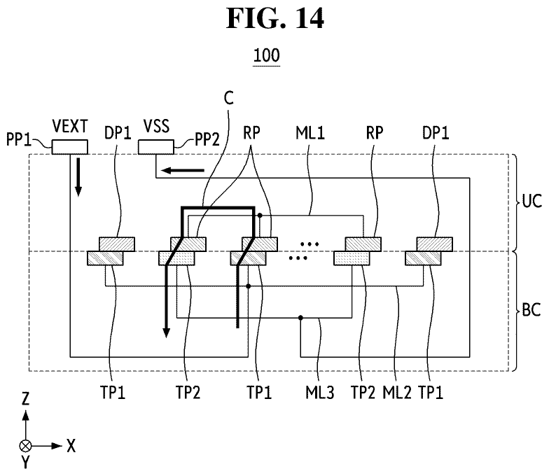

FIG. 14 is a cross-sectional view taken along D-D′ of FIG. 13.

Referring to FIG. 14, since the plurality of first connectors RP of the upper chip UC are electrically connected to each other, when some of the plurality of first connectors RP at least partially overlap the first test connector TP1 of the lower chip BC in the first direction Z, and others of the plurality of first connectors RP at least partially overlap the second test connector TP2 of the lower chip BC in the first direction Z, a short circuit may be formed between the first test connector TP1 and the second test connector TP2. A current C may flow between the first test connector TP1 and the second test connector TP2 due to a voltage difference between the first test connector TP1 and the second test connector TP2. The flow of the current C may be checked through the first probing pad PP1 and the second probing pad PP2, and it may be evaluated that a misalignment has occurred in the memory device 100 (or memory device 100 may be evaluated that the misalignment is at an unallowable level).

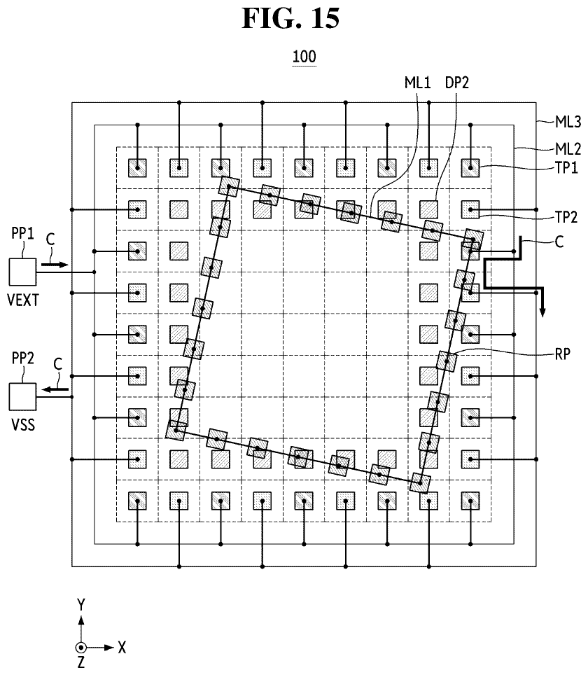

FIG. 15 is an enlarged plan view showing a partial region of the memory device.

FIG. 15 shows the first connector RP, the plurality of first and second test connectors TP1 and TP2, and the plurality of second dummy connectors DPA2 when the memory device 100 is viewed in the first direction Z, after the upper chip and the lower chip are bonded (unlike FIG. 13, the first dummy connector DPA1 is not shown). Other connectors except for the shown connectors are not shown for brevity. Also, the above-mentioned first to third wiring lines ML1 to ML3, the plurality of first connectors RP, the plurality of first and second test connectors TP1 and TP2, the plurality of first connectors RP, the plurality of first and second dummy connectors DPA1 and DPA2, and the first and second probing pads PP1 and PP2 will not be described.

Referring to FIG. 15, when the upper chip and the lower chip are bonded, unlike FIGS. 13 and 14, the upper chip may rotate around the first direction Z, and may be bonded to the lower chip. Therefore, some of the plurality of first connectors RP may unintentionally overlap at least partially the first test connector TP1 in the first direction Z, and others of the plurality of first connectors RP may unintentionally overlap at least partially the second test connector TP2 in the first direction Z. In this case, the connectors of the upper chip and the lower chip come into contact with other connectors other than the designating connectors. If the connectors that are not designated to each other come into contact with each other, the memory device may malfunction.

Similarly, a current C may flow between the first test connector TP1 and the second test connector TP2, due to a voltage difference between the first test connector TP1 and the second test connector TP2. The flow of the current C may be checked through the first probing pad PP1 and the second probing pad PP2, and it may be evaluated that a misalignment has occurred in the memory device 100 (or the memory device 100 may be evaluated that the misalignment is at an unallowable level).

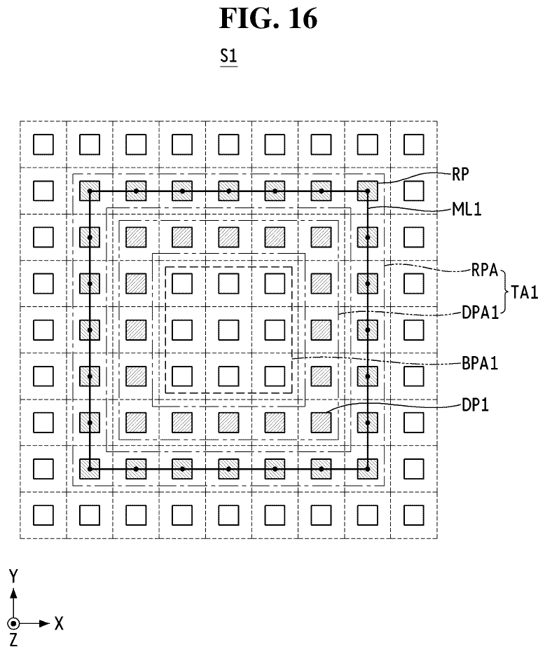

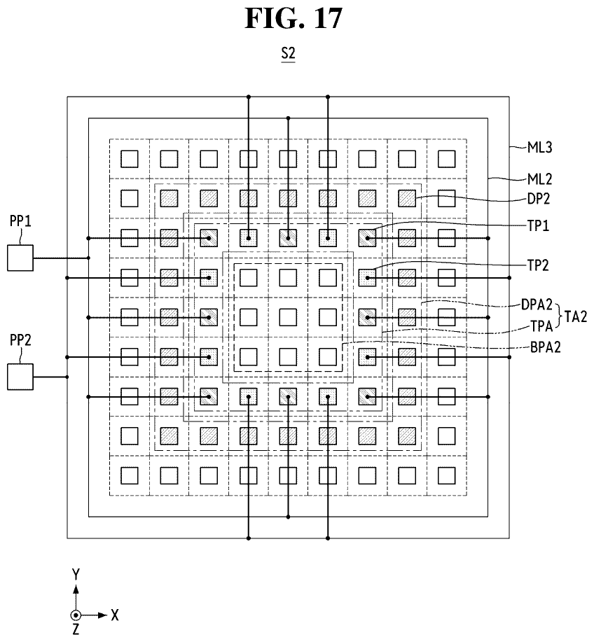

FIG. 16 is a plan view showing a partial region on the first surface of the upper chip. FIG. 17 is a plan view showing a partial region on the second surface of the lower chip.

The first and second probing pads PP1 and PP2 and the first to third wiring lines ML1, ML2 and ML3 shown in FIGS. 16 and 17 will not be described.

Referring to FIGS. 16 and 17, unlike FIG. 6, on the first surface S1, the first region RPA may surround the first dummy region DPA1 from the outside. The first dummy region DPA1 may surround a part of the first normal region BPA1 from the outside. On the second surface S2, the second dummy region DPA2 may surround the second region TPA from the outside. The second region TPA may surround a part of the second normal region BPA2 from the outside. When the upper chip and the lower chip are bonded, the plurality of first connectors RP of the first region RPA and the plurality of second dummy connectors DP2 of the second dummy region DPA2 may at least partially overlap each other. Also, each of the plurality of first dummy connectors DP1 of the first dummy region DPA1 and each of the plurality of first and second test connectors TP1 and TP2 of the second region TPA may overlap at least partially.

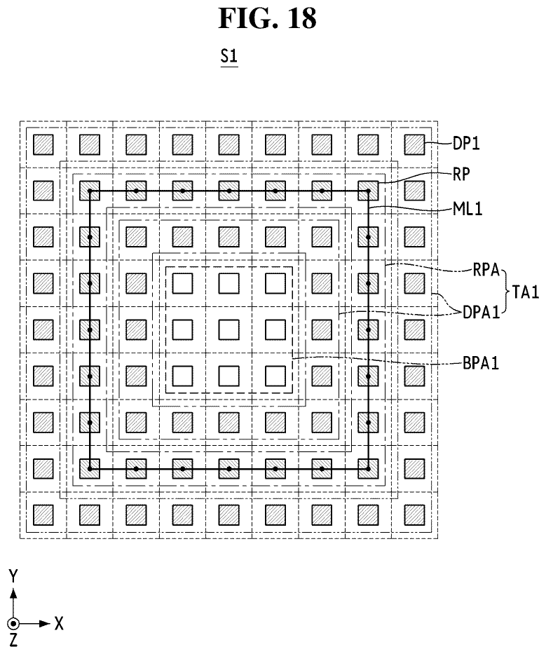

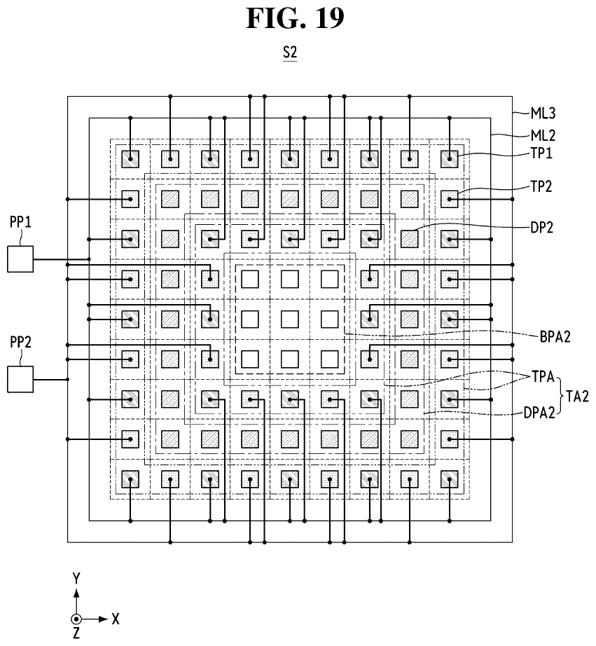

FIG. 18 is a plan view showing a partial region on the first surface of the upper chip. FIG. 19 is a plan view showing a partial region on the second surface of the lower chip.

The first and second probing pads PP1 and PP2 and the first to third wiring lines ML1, ML2 and ML3 shown in FIGS. 18 and 19 will not be described. Referring to FIGS. 18 and 19, in addition to FIG. 6, a first dummy region DPA1 may be further formed on the first surface S1. A part of the first dummy region DPA1 may surround the first normal region BPA1 from the outside, and may be surrounded by the first region RPA. Another part of the first dummy region DPA1 may surround the first region RPA from the outside. Also, a second region TPA may be further formed on the second surface S2. A part of the second region TPA may surround the second normal region BPA2 from the outside, and may be surrounded by the second dummy region DPA2. Another part of the second region TPA may surround the second dummy region DPA2 from the outside.

When the upper chip and the lower chip are bonded, each of the plurality of first connectors RP of the first region RPA and each of the second plurality of dummy connectors DP2 of the second dummy region DPA2 may overlap at least partially. Also, each of the plurality of first dummy connectors DP1 of the first dummy region DPA1 and each of the plurality of first and second test connectors TP1 and TP2 of the second region TPA may overlap at least partially.

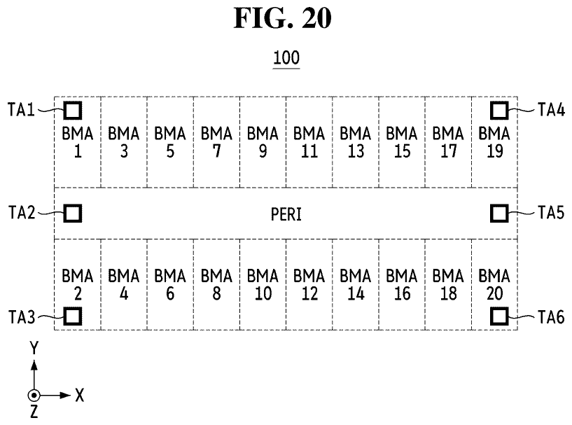

FIG. 20 is a plan view of a memory device for explaining a test region.

For convenience of explaining the test region, the memory device 100 will be described using a plan view, but the test region may, of course, be formed in all the surfaces on which the upper chip and the lower chip touch each other as described above (for example, the first and second surfaces of FIGS. 6 and 7). Referring to FIG. 20, there may be a plurality of test regions in the memory device 100. For example, the first to fourth test regions TA1 to TA4 among the plurality of test regions may be disposed inside the first, second, nineteenth, and twentieth bank memory arrays BMA1, BMA2, BMA19, and BMA20, among the plurality of bank memory array regions BMA1 to BMA20 so as to be surrounded by each of the first, second, nineteenth, and twentieth bank memory arrays BMA1, BMA2, BMA19, and BMA20. The fifth and sixth test regions TA5 and TA6 may be disposed inside the peripheral circuit region PERI so as to be surrounded by the peripheral circuit region PERI. Although six test regions are shown in FIG. 20, example embodiments are not limited thereto, and more or fewer test regions may be formed in the memory device 100, and the disposed positions are also not limited. The region in the memory device 100 other than the test region is a normal region, and connectors for sending and receiving signals required for or used during the operation of the memory cells of the memory device 100 may be disposed therein.

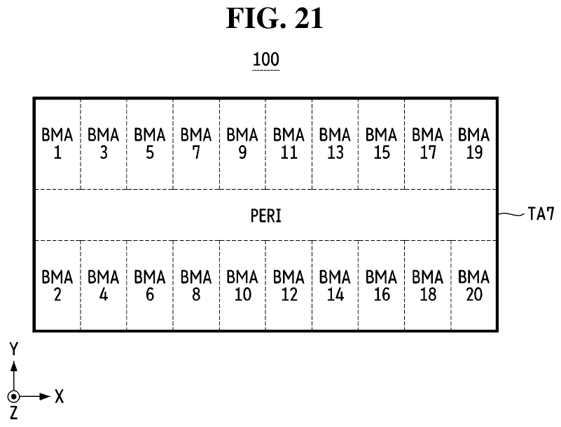

FIG. 21 is a plan view of the memory device for explaining the test region.

For convenience, the test region will be described using a plan view of the memory device 100. However, as described above, the test region may, of course, be formed on all the surfaces in which the upper chip and the lower chip touch each other (for example, the first and second surfaces of FIGS. 6 and 7). Referring to FIG. 20, the test region in the memory device 100 may surround the outside of the memory device 100. For example, a seventh test region TA7 may be formed to surround all of the bank memory array regions BMA1 to BMA20 and the peripheral circuit region PERI. The region other than the test region in the memory device 100 is a normal region, and connectors for sending and receiving the signals required for or used during the operation of the memory cells of the memory device 100 may be disposed therein. That is to say, the seventh test region TA7 may be formed outside the normal region to surround the normal region.

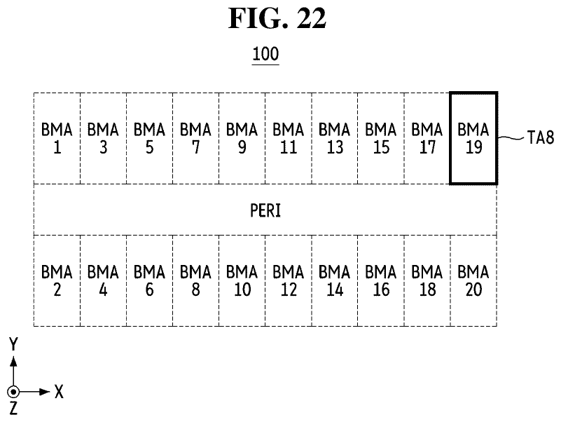

FIG. 22 is a plan view of the memory device for explaining the test region.

For convenience, although the test region will be described using a plan view of the memory device 100, the test region may, of course, be formed on all the surfaces in which the upper chip and the lower chip touch each other as described above (for example, the first and second surfaces of FIGS. 6 and 7). Referring to FIG. 22, the test region in the memory device 100 may be formed outside a part of the plurality of bank memory array regions BMA1 to BMA20 to surround a part of the plurality of bank memory array regions BMA1 to BMA20. For example, an eighth test region TA8 may be formed outside the nineteenth bank memory array region BMA19 to surround the entire nineteenth bank memory array region BMA19 among the plurality of bank memory array regions BMA1 to BMA20. Unlike this, the eighth test region TA8 may be formed outside the peripheral circuit region PERI to surround the peripheral circuit region PERI. The region other than the test region in the memory device 100 is a normal region, and connectors for sending and receiving a signal required for or used during the operation of the memory cells of the memory device 100 may be disposed therein.

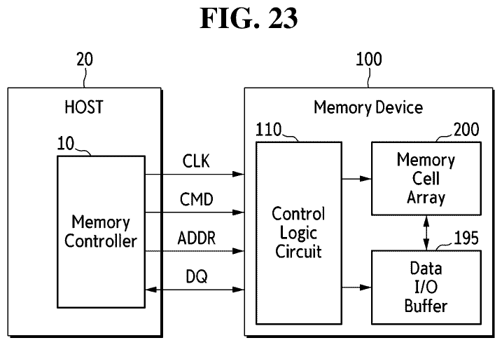

FIG. 23 is a block diagram showing a memory system.

Referring to FIG. 23, a host device 20 may include a memory controller 10. That is, unlike the memory system described referring to FIG. 1 in which the memory controller 10 is disposed outside the host device 20, the host device 20 according to some example embodiments may include the memory controller 10. The host device 20 may control the memory device 100 through the memory controller 10. Here, the host device 20 may communicate with the memory device 100 on the basis of any of standards such as one or more of DDR (Double Data Rate), LPDDR (low power double data rate), GDDR (Graphics Double Data Rate), Wide I/O, HBM (High Bandwidth Memory), HMC (Hybrid Memory Cube) or CXL (Compute eXpress Link).

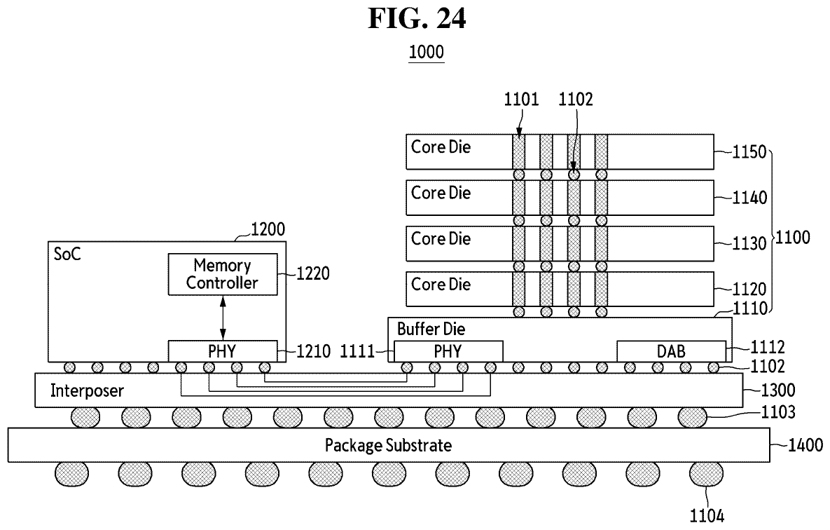

FIG. 24 is a diagram of a semiconductor package.

Referring to FIG. 24, a semiconductor package 1000 may include a stacked memory device 1100, a system-on-chip 1200, an interposer 1300, and a package substrate 1400. The stacked memory device 1100 may include a buffer die 1110 and core dies 1120 to 1150. The core dies 1120 to 1150 may include the memory device 100 described referring to FIGS. 1 to 22. The buffer die 1110 may include a physical layer 1111 and a direct access region (DAB) 1112. The physical layer 1111 may be electrically connected to a physical layer 1210 of the system-on-chip 1200 through an interposer 1300. The stacked memory device 1100 may receive a signal from the system-on-chip 1200 or transmit the signal to the system-on-chip 1200 through the physical layer 1111.

The direct access region 1112 may provide an access path that may test the stacked memory device 1100 without going through the system-on-chip 1200. The direct access region 1112 may include conductive means (e.g., ports or pins) that may communicate directly with the external test device. Test signals and data received through the direct access region 1112 may be sent to the core dies 1120 to 1150 through the TSVs. Data that are read from the core dies 1120 to 1150 for testing of the core dies 1120 to 1150 may be sent to the test device through the TSVs and the direct access region 1112. Accordingly, a direct access test may be performed on the core dies 1120 to 1150.

The buffer die 1110 and the core dies 1120 to 1150 may be electrically connected to each other through the TSVs 1101 and the bumps 1102. The buffer die 1110 may receive signals provided to each channel from the system-on-chip 1200 through the bumps 1102 assigned for each channel. For example, the bumps 1102 may be or may include micro bumps.

The system-on-chip 1200 may execute the applications supported by the semiconductor package 1000, using the stacked memory device 1100. For example, the system-on-chip 1200 may execute specialized computations, by including at least one processor of at least one of a CPU (Central Processing Unit), an AP (Application Processor), a GPU (Graphic Processing Unit), an NPU (Neural Processing Unit), a TPU (Tensor Processing Unit), a VPU (Vision Processing Unit), an ISP (Image Signal Processor), and a DSP (Digital Signal Processor).

The system-on-chip 1200 may include a physical layer 1210 and a memory controller 1220. The physical layer 1210 may include I/O circuits for sending and receiving signals to and from the physical layer 1111 of the stacked memory device 1100. The system-on-chip 1200 may provide various signals to the physical layer 1111 through the physical layer 1210. The signals provided to the physical layer 1111 may be transferred to the core dies 1120 to 1150 through the interface circuits of the physical layer 1111 and the TSVs 1101.

The memory controller 1220 may control the overall operation of the stacked memory device 1100. The memory controller 1220 may send the signals for controlling the stacked memory device 1100 to the stacked memory device 1100 through the physical layer 1210. The memory controller 1220 may correspond to the memory controller 10 of FIG. 1.

An interposer 1300 may connect the stacked memory device 1100 and the system-on-chip 1200. The interposer 1300 may connect between the physical layer 1111 of the stacked memory device 1100 and the physical layer 1210 of the system-on-chip 1200, and may provide physical paths formed using the conductive materials. As a result, the stacked memory device 1100 and the system-on-chip 1200 may be stacked on the interposer 1300 to send and receive the signals to and from each other.

Bumps 1103 may be attached to an upper part of the package substrate 1400, and solder balls 1104 may be attached to a lower part thereof. For example, the bumps 1103 may be flip-chip bumps. The interposer 1300 may be stacked on the package substrate 1400 through the bumps 1103. The semiconductor package 1000 may send and receive signals to and from other external packages or semiconductor devices through the solder balls 1104. For example, the package substrate 420 may be a printed circuit board (PCB).

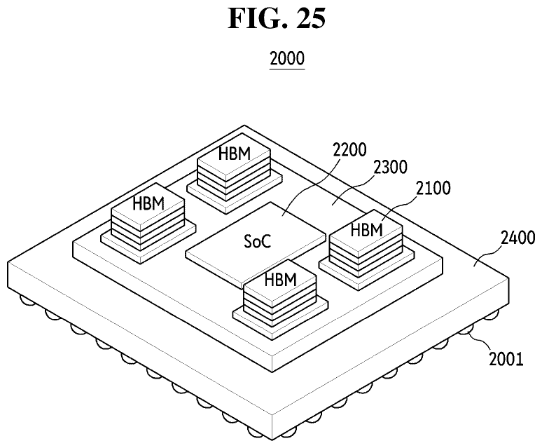

FIG. 25 is a diagram of an implemented example of a semiconductor package.

Referring to FIG. 25, a semiconductor package 2000 may include a plurality of stacked memory devices 2100 and a system-on-chip 2200. The stacked memory devices 2100 and the system-on-chip 2200 may be stacked on an interposer 2300, and the interposer 2300 may be stacked on a package substrate 2400. The semiconductor package 2000 may send and receive the signals to and from other external packages or semiconductor devices through solder balls 2001 attached to the lower part of the package substrate 2400.

Each of the stacked memory devices 2100 may be implemented on the basis of a HBM standard. However, example embodiments are not limited thereto, and each of the stacked memory devices 2100 may be implemented on the basis of GDDR, HMC, or Wide I/O standard. Each of the stacked memory devices 2100 may correspond to the stacked memory device 1100 of FIG. 24.

The system-on-chip 2200 may include at least one processor, such as a CPU, an AP, a GPU or an NPU, and a plurality of memory controllers for controlling a plurality of stacked memory devices 2100. The system-on-chip 2200 may send and receive signals to and from corresponding stacked memory devices through the memory controller. The system-on-chip 2200 may correspond to the system-on-chip 1200 of FIG. 24.

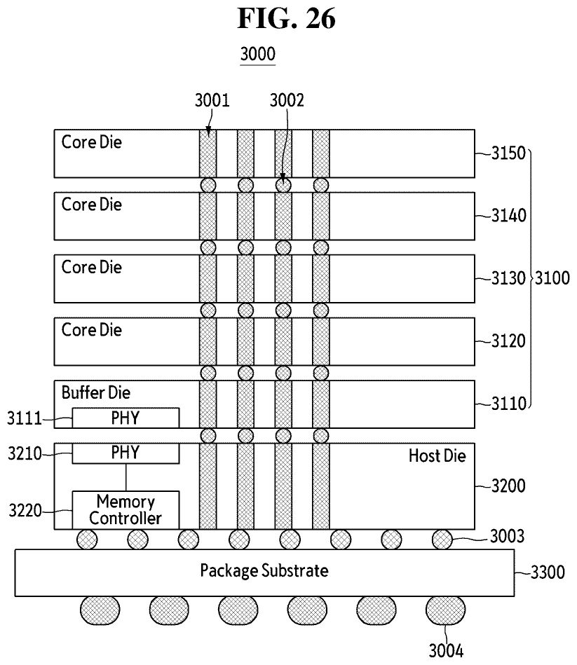

FIG. 26 is a diagram of a semiconductor package.

Referring to FIG. 26, a semiconductor package 3000 may include a stacked memory device 3100, a host die 3200, and a package substrate 3300. The stacked memory device 3100 may include a buffer die 3110 and core dies 3120 to 3150. The buffer die 3110 may include a physical layer 3111 for communicating with the host die 3200, and each of the core dies 3120 to 3150 may include a memory cell array.

The host die 3200 may include a physical layer 3210 for communicating with the stacked memory device 3100, and a memory controller 3220 for controlling some or all such as the overall operation of the stacked memory device 3100. In addition, the host die 3200 may include a processor for controlling operations such as the overall operation of the semiconductor package 3000 and executing applications supported by the semiconductor package 3000. For example, the host die 3200 may include at least one processor, such as a CPU, an AP, a GPU, and an NPU.

The stacked memory device 3100 may be disposed on the host die 3200 on the basis of the TSV 3001 and vertically stacked on the host die 3200. Thus, the buffer die 3110, the core dies 3120 to 3150, and the host die 3200 may be electrically connected to each other through the TSV 3001 and the bumps 3002 without an interposer. For example, the bumps 3002 may be micro-bumps.

Bumps 3003 may be attached to the upper part of the package substrate 3300, and solder balls 3004 may be attached to the lower part thereof. For example, the bumps 3003 may be flip-chip bumps. The host die 3200 may be stacked on the package substrate 3300 through the bumps 3003. The semiconductor package 3000 may send and receive signals to and from other external packages or semiconductor devices through the solder balls 3004.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, at least one of a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

Although some example embodiments have been described with reference to the accompanying drawings, example embodiments are not limited to the above, but may be implemented in various different forms. A person of ordinary skill in the art may appreciate that some example embodiments may be practiced in other concrete forms without changing the technical spirit of inventive concepts. Therefore, it should be appreciated that example embodiments as described above is not restrictive but illustrative in all respects. Example embodiments are not necessarily mutually exclusive. For example, some example embodiments may include one or more features described with reference to one or more figures, and may also include one or more other features described with reference to one or more other figures.

1. A memory device comprising:
a first chip including a first normal region and a first test region, the first normal region including a plurality of first normal connectors on a first surface and configured to be provided with signals used during an operation of memory cells, and the first test region including a plurality of first connectors on the first surface and electrically connected to each other; and
a second chip bonded to the first chip in a first direction,
wherein the second chip includes,
a second normal region including a plurality of second normal connectors on a second surface touching with the first surface to at least partially overlap the plurality of first normal connectors in the first direction, and configured to provide signals used during the operation of the memory cells to the first normal connectors, and
a second test region including a plurality of first and second test connectors on the second surface so as not to overlap the plurality of first connectors in the first direction, and configured to not be provided with signals used during the operation of the memory cells.

2. The memory device of claim 1,
wherein the second test region further includes a plurality of second dummy connectors on the second surface to overlap at least partially the plurality of first connectors in the first direction.

3. The memory device of claim 2,
wherein the plurality of first and second test connectors are alternately adjacent to each other on the second surface to surround the plurality of second dummy connectors from the outside.

4. The memory device of claim 2,
wherein the plurality of first and second test connectors are alternately adjacent to each other on the second surface so as to be surrounded by the plurality of second dummy connectors.

5. The memory device of claim 1, further comprising:
first and second probing pads,
wherein the plurality of first test connectors are electrically connected to the first probing pad, and the plurality of second test connectors are electrically connected to the second probing pad.

6. The memory device of claim 1,
wherein the plurality of first test connectors are configured to be supplied with a first voltage during a misalignment test, and the plurality of second test connectors are configured to be supplied with a second voltage different from the first voltage during the misalignment test.

7. The memory device of claim 1,
wherein the first test region is outside the first normal region and surrounds the first normal region, and
the second test region is outside the second normal region and surround the second normal region.

8. The memory device of claim 1,
wherein the first normal region includes a first memory array region and a first peripheral circuit region,
the first test region is inside the first memory array region or inside the first peripheral circuit region so as to be surrounded by the first memory array region or the first peripheral circuit region, respectively,
the second normal region includes a second memory array region and a second peripheral circuit region, and
the second test region is inside the second memory array region or the second peripheral circuit region so as to be surrounded by the second memory array region or the second peripheral circuit region, respectively.

9. The memory device of claim 1,
wherein the first normal region includes a first memory array region and a first peripheral circuit region,
the first memory array region includes a first bank memory array region,
the first test region is outside the first bank memory array region or the first peripheral circuit region to surround the first bank memory array region or the first peripheral circuit region, respectively,
the second normal region includes a second memory array region and a second peripheral circuit region,
the second memory array region includes a second bank memory array region, and
the second test region is outside the second bank memory array region or the second peripheral circuit region to surround the second bank memory array region or the second peripheral circuit region, respectively.

10. The memory device of claim 1,
wherein the plurality of first test connectors are electrically connected to each other by a first wiring line, and the plurality of second test connectors are electrically connected to each other by a second wiring line that is not connected to the first wiring line.

11. A memory device comprising:
a first chip including a plurality of first connectors on a first surface and electrically connected to each other;
a second chip bonded to the first chip in a first direction, and including a plurality of first and second test connectors on a second surface touching with the first surface so as not to overlap the plurality of first connectors in the first direction; and
first and second probing pads,
wherein the plurality of first test connectors are connected to the first probing pad, and the plurality of second test connectors are connected to the second probing pad, and
the plurality of first connectors and the plurality of first and second test connectors are configured to not be used to send and receive signals associated with an operation of memory cells.

12. The memory device of claim 11,
wherein the second chip further includes a plurality of second dummy connectors on the second surface to overlap at least partially the plurality of first connectors in the first direction.

13. The memory device of claim 12,
wherein the plurality of first and second test connectors are adjacent to each other and alternately on the second surface to surround the plurality of second dummy connectors from the outside.

14. The memory device of claim 12,
wherein the plurality of first and second test connectors are adjacent to each other and alternately on the second surface so as to be surrounded by the plurality of second dummy connectors.

15. The memory device of claim 11,
wherein the plurality of first test connectors are configured to be supplied with a first voltage during a misalignment test, and the plurality of second test connectors are configured to be supplied with a second voltage different from the first voltage during the misalignment test.

16. The memory device of claim 11,
wherein the plurality of first test connectors are electrically connected to each other by a first wiring layer, and the second test connectors are electrically connected to each other by a second wiring layer that is not connected to the first wiring layer.

17. The memory device of claim 16,
wherein the first probing pad is electrically connected to the first wiring layer, and the second probing pad is electrically connected to the second wiring layer.

18. The memory device of claim 11,
wherein the first chip further includes
a first normal region including a plurality of first normal connectors on the first surface and configured to be provided with signals used during operation of the memory cell, and
a first test region different from the first normal region on the first surface,
wherein the plurality of first connectors are included in the first test region, and
the second chip further includes a second normal region including a plurality of second normal connectors on the second surface to overlap at least partially the plurality of first normal connectors, and configured to be provided with signals used during operation of the memory cell, and
a second test region different from the first normal region on the second surface,
wherein the plurality of first and second test connectors are included in the second test region.

19. The memory device of claim 18,
wherein the first test region is outside the first normal region to surround the first normal region, and
the second test region is outside the second normal region to surround the second normal region.

20.-21. (canceled)

22. A memory device comprising:
a first chip including a plurality of first connectors on a first surface facing a first direction and electrically connected to each other; and
a second chip bonded to the first chip in the first direction, and including a plurality of first and second test connectors on a second surface touching with the first surface so as not to overlap the plurality of first connectors in the first direction,
wherein the plurality of first test connectors are configured to be supplied with a first voltage during a misalignment test, and
the plurality of second test connectors are configured to be supplied with a second voltage different from the first voltage during the misalignment test.

23.-27. (canceled)
